(19) United States
(12) Patent Application Publication
(10) Pub. No.: US 2015/0077107 A1
(43) Pub. Date: Mar. 19, 2015

(54) Method for B0 Field Correction in Magnetic Resonance

(71) Applicant: National Research Council of Canada, Ottawa (CA)

(72) Inventors: Jonathan Curnow Sharp, Calgary (CA); Scott King, Winnipeg (CA)

(73) Assignee: National Research Council of Canada, Ottawa, ON (CA)

(21) Appl. No.: 14/395,700

(22) PCT Filed: Apr. 19, 2013
(86) PCT No.: PCT/CA2013/000371

§ 371 Date: Oct. 20, 2014

Related U.S. Application Data
(60) Provisional application No. 61/635,538, filed on Apr. 19, 2012.

(51) Int. Cl. G01R 33/3875; G01R 33/46; G01R 33/565

(52) U.S. Cl. CPC G01R 33/3875; G01R 33/56563; G01R 33/4625
USPC 324/309; 324/318

(57) ABSTRACT

In a magnetic resonance (MR) experiment, a method for effectively improving B0 uniformity of a static magnet of a magnetic resonance (MR) apparatus, without shimming magnets or coils involves combining a plurality of RF receive fields, each having a different respective sensitivity map. This method can apply retrospectively to previously acquired data, as long as there is data from different receive fields.

### FIELD OF THE INVENTION

The present invention relates in general to B0 field corrections in magnetic resonance, and in particular to shimming of the B0 field including shimming with temporal variation using a plurality of RF receive signals, each having a respective field sensitivity that varies across the sample volume.

### BACKGROUND OF THE INVENTION

In magnetic resonance (MR) the main static magnetic field is known as B0. Very high homogeneity of the B0 field is typically required. Field inhomogeneities (also known as off-resonance effects) can cause a variety of problems with output data. For example, in NMR spectroscopy (also known as MRS—magnetic resonance spectroscopy) field inhomogeneity causes broadened spectral lines, which decreases signal-to-noise-ratio (SNR) and can also cause neighbouring lines to overlap. Field homogeneity is also important in imaging. Inhomogeneity can cause geometric distortions in the phase-encoding (blipped gradient) direction. Signal loss (or drop-out) can also occur. Echo planar imaging (EPI) pulse sequences are especially sensitive to off-resonance effects.

The first approach to improving B0 homogeneity is to provide static shimming magnets (or low frequency coils) that improve the uniformity of the B0 field (in terms of amplitude and orientation) locally, especially locally, where the field is less uniform. These shimming magnets have been used since the dawn of MR. Even if a magnet is initially perfectly shimmed, magnetic susceptibility variations of the sample (or patient) can impair the homogeneity. In practice, the causes of B0 inhomogeneity include: an imperfectly shimmed magnet, sample magnetic susceptibility variations, eddy currents, patient motion, equipment instabilities, sample instabilities, and others. The resulting inhomogeneities are particularly problematic for in vivo MR.

Some of these can be corrected by adjusting currents in shim magnets (i.e. electromagnets or low frequency EM coils built-into typical MR systems), but it is common that this correction is imperfect. Some corrections are sample dependent, and will not necessarily be known until after the MR procedure is performed, and some corrections would theoretically require variation of the shim magnets during the acquisition window, which is difficult, if even plausible. It has not been suggested in the art to vary a shimming field during a MR procedure, and the problems with doing so in terms of timings would be insurmountable with current equipment.

Some procedures exist for correction of data corrupted by acquisition within an inhomogeneous field. For spectroscopy resolution-enhancement filtering can be applied in some cases. For image distortion in EPI there are a range of geometric correction techniques. Some of these may inherently provide shimming that corrects B0 field inhomogeneities that are constant over a receive window.

It is also known in various corners of the art to use receiver arrays of RF coils, For example, coil arrays are commonly used in MRI in conjunction with multi-channel receiver systems. One application is to improve a signal to noise ratio (SNR).

Another main application of multi-channel receives is for use in parallel imaging experiments. In these experiments, spatial information derived from the different spatial sensitivities of the different coil array elements is used in the image reconstruction. This allows images to be reconstructed using less acquired NMR data, so results in a faster imaging experiment (accelerated imaging). Methods such as SMASH, GRAPPA and SENSE allow unfolding of images to be performed to increase the field of view (FOV) of the imaging experiment.

“SENSE Shimming” is a technique known in the art that uses multi-coil FID data to measure field inhomogeneity (i.e. it is a field mapping method). It uses unlocalized FID data. After mapping, the shim coil currents are adjusted (usual shimming procedure). No data post-processing is performed to optimize for effects of inhomogeneity.

The ‘SMASH’ family of methods (including SMASH (3), AUTO-SMASH (4), VD-AUTO-SMASH (5), GRAPPA(6)) make use of a set of receive fields. In the SMASH family of techniques the k-space location of the receive data is modified, so that k-space data points that are not acquired directly can be synthesized from multi-channel acquired data. SMASH uses a sensitivity function of the form of a complex exponential, which leads to a k-space shift in the detection process. This is equivalent to the phase gradient when using a spiral birdcage as a receiver, except that by using an array of receiver coils different phase gradient can be synthesized.

The purpose of the SMASH methods is to increase image field-of-view (FOV) by filling in missing k-space data points, allowing faster imaging acquisition, and does not purport to correct B0 field inhomogeneities. SMASH methods are also only applicable to imaging experiments.

There are also other applications for multi-channel data. For example, the SURE-SENSE method uses multi-channel data to increase image resolution. Furthermore, multiple receivers have also been used in spectroscopy for SNR improvement.

Ordidge (9) proposes a method for time-domain correction to improve spectral lineshapes distorted by eddy currents. This method does not make use of multiple receiver coils and does not compensate for field inhomogeneities.

There remains a need for a method for improving shimming or more generally B0 field inhomogeneity, especially one that does not require complex and expensive shimming coils, or control circuitry for operating the shimming coils.

### SUMMARY OF THE INVENTION

Applicant has discovered a method for effectively improving homogeneity of B0 field using magnetic resonance, which makes use of multiple signals acquired from the same sample (e.g. using an array of receiver coils), to correct post-acquisition for the effects of errors in the B0 field (i.e. inhomogeneities). The method can also deal with time-varying errors, such as can arise due to eddy currents induced by the gradient switching hardware.

Accordingly a method is provided for correcting for B0 non-uniformity in a static magnet of a magnetic resonance (MR) apparatus. The method comprises: obtaining a respective, different, field sensitivity map as a function of a sample volume for each of a plurality of RF receive fields of receiver equipment of the MR apparatus; identifying a non-uniformity of the B0 magnetic field to be corrected; and computing with the field sensitivity maps and the identified non-uniformity, a combination of the RF receive fields as a function of time that reduces artifacts in an MR signal acquired by the receiver equipment due to the identified non-uniformity.

Obtaining field sensitivity maps may comprise mapping a field sensitivity for: each RF coil of an array of RF coils included in the receive equipment; each of a plurality of separate RF coils included in the receive equipment; and a RF coil in each of a plurality of positions, orientations and configurations in which the RF coil is adapted to be held during respective sample intervals of a MR procedure. Obtaining field sensitivity maps may comprise characterizing reception sensitivities of respective receiver coils. Obtaining field sensitivity maps may comprise characterizing reception sensitivities of a receiver coil for each of a plurality of transmit coil spatial variations.

Computing the combination of the RF receive fields may comprise defining a weighted sum of the acquired MR signals is used to synthesize a new MR signal. The weighted summation is performed in the time domain. Each of the MR signals may consist of a data stream of digitized samples constituting a free induction decay (FID) signal or an echo. The weights applied to respective samples to generate the synthesized MR signal may be different for different samples of a same acquisition window. Each digitized sample may be a complex value, wherein the weights are defined by a weighting function that varies across the acquisition window both in amplitude and phase.

Computing the combination of the RF receive fields may comprise computing: a detection frequency gradient to correct for a linear B0 field gradient error; a sample weighting function to correct for a non-linear B0 field gradient error; a sample weighting function to correct for a time-varying B0 error field; and/or a sample weighting function selected by applying an error limiting procedure to limit noise amplification.

The method may further comprise providing MR signals associated with each receive field, and applying the combination to the MR signals to obtain a B0 corrected MR signal. Application of the combination to the MR signals may be used to compute an error function used in the error limiting procedure, such as regularized optimization.

The method may iteratively perform the computing of the combination and the applying the combination to improve an approximation of the non-uniformity.

The method may further comprise placing a sample in the sample volume of the MR apparatus; and performing a MR process that includes acquiring the RF signals from the receiver equipment associated with each of the RF receive fields.

Further features of the invention will be described or will become apparent in the course of the following detailed description.

### BRIEF DESCRIPTION OF THE DRAWINGS

In order that the invention may be more clearly understood, embodiments thereof will now be described in detail by way of example, with reference to the accompanying drawings, in which:

FIG. 1 is a schematic flow chart showing principal method steps in accordance with an embodiment the invention;

FIGS. 2a,b are photographs of a magnetic resonance spectroscopy setup used to demonstrate the present invention;

FIG. 3 is a schematic illustration of the magnetic resonance spectroscopy setup of FIGS. 2a,b;

FIG. 4 is a pulse sequence diagram of a MRS procedure applied using magnetic resonance spectroscopy setup of FIGS. 2a,b;

FIG. 5 shows time and frequency domain graphs of FIDs obtained with coil 1;

FIG. 6 shows time and frequency domain graphs of FIDs obtained with coil 2;

FIG. 7 shows time and frequency domain graphs of FIDs obtained with a coil synthesized from coils 1 and 2 in accordance with an embodiment of the invention;

FIG. 8 shows spectra from coil 1 and the synthesized coil, respectively;

FIGS. 9a,b are photographs of a magnetic resonance imaging setup used to demonstrate the present invention;

FIG. 10 is a schematic illustration of the magnetic resonance imaging setup of FIGS. 9a,b;

FIG. 11 are coil sensitivity maps of the 8 coils of the magnetic resonance imaging setup of FIGS. 9a,b;

FIG. 12 is a pulse sequence diagram of a MRS procedure applied using magnetic resonance spectroscopy setup of FIGS. 2a,b;

FIG. 13 is an amplitude emf of a time series of echos produced using a synthesized coil from coils 1 to 8 in accordance with an embodiment of the invention;

FIGS. 14a,b are MR images of a slice showing shimmed and de-shimmed sum of squares images;

FIGS. 15a,b are MR images of a slice showing uncorrected and corrected images;

FIGS. 16a,b are difference images that show the subtle differences between the shimmed and deshimmed sum of squares images, and the difference between positive and negative correction, respectively; and

FIGS. 17a,b are a panel of graphs of an experimental demonstration of DEFG shimming in MRS, including A) raw, unprocessed FIDs from a 2 channel array with a shim offset of 1 μT/m, B) the FIDs of A) with time-domain weighting functions applied (before summation) to generate a DEFG of 0.3 deg/ms; C) two reconstructions for comparison of DEFG shimming with one without; D) the FT part of the signals in part C), and E) plots of spectral line width evaluated using full-width at half maximum as a function strength of DEFG correction.

### DESCRIPTION OF PREFERRED EMBODIMENTS

In any NMR or MRI experiment, following spin excitation, the nuclear magnetization precesses at the resonant frequency, as determined by the Larmor Equation: ω₀=−γ(1−σ)B0 (where γ is the gyromagnetic ratio, σ is the chemical-shift shielding) For MR detection using a coil array, spin precession results in an electromagnetic field having a frequency ω_{EMF} detected at each receive coil following amplification. Usually ω_{EMF}=ω₀, meaning the input frequency presented to the detector (due to field precession) is the same as the detector output frequency. The present invention introduces the concept of detection frequency (ω_{D}) defined as: ω_{D}=ω_{EMF}−ω_{O}. By selecting a weighted sum of MR signals acquired from multiple detector coils, new MR signals can be synthesized. This is equivalent to the synthesis of a new receive field, that effectively has a frequency of the detected signal dependent upon location within the sample. In this way a receive field with a detection frequency gradient can be created for a linear correction. Alternatively non-linear and time-varying shimming can be embedded into the synthesized receive field. This allows for the correction of an inhomogeneity of the static B₀ field, i.e. shimming (for a static B₀-gradient) or eddy-current compensation (for a dynamic B₀-gradient that varies during the acquisition window).

A very high order of shimming can be provided by effectively shimming voxel-by-voxel, according to the present invention. Furthermore, the method may be applied retrospectively, after the data has been collected. With sufficient computer resources, imaging can be improved even without prior knowledge of the field inhomogeneity, by iterative processing. The present technique can generate corrections that are impossible with conventional shimming restricted to spherical harmonic corrections. The technique does not require specific hardware to implement, is completely complementary with other known shimming methods, and can be applied in all types of MR imaging and spectroscopy. Reliance on retrospective shimming may reduce demands on shimming equipment within MR equipment, offering substantial advantages. In situations where a desired B0 correction changes during acquisition (instabilities in the sample, or patient, or equipment), the present technique has great advantage. The technique is particularly valuable for large voxel applications, such as in vivo MR spectroscopy, or wide slice imaging, and is also applicable to functional MRI (fMRI), brain imaging, cardiac spectroscopy, etc. It is noted that possible target volumes include: an NMR test-tube sample; a localized single voxel (e.g. PRESS MRS method); any of a set of localized voxels (chemical shift imaging); and a single voxel in MRI (with dephasing in the slice direction). In the case of a set of voxels, the detection frequency gradient method is equivalent to very high order shimming.

The most compelling application for this invention in the area of MR imaging is for echo planar imaging (EPI). These applications include functional MRI (fMRI) and diffusion or fiber-tracking methods. EPI is sensitive to B0 errors, which cause geometric distortions and also sometimes signal loss in the images. For techniques such as fMRI, which rely on detection of small differences between repeated images, small time-dependent shimming errors can be critical. If these errors can be corrected retrospectively, then this could lead to significant improvements in image quality.

FIG. 1 is a flowchart showing principal steps involved in correction of a B0 field inhomogeneity, in accordance with an embodiment of the present invention. At step 10, sensitivity maps of a plurality of receive fields is provided. As is known in the art, receive field sensitivities can be computed in a few ways empirically, theoretically (RF field modelling) or using both. For example, autocalibration techniques can be invoked to calculate the maps by iterative approximation, similar to how later versions of SMASH (AUTO-SMASH, VD-AUTO-SMASH, and GRAPPA) use autocalibration procedures. The autocalibration may involve computing combinations (see steps below) for the same system with data that has slightly different shimming. It is known to obtain field sensitivity maps using a known phantom.

The receive field sensitivity is not independent of the MR process, but varies with a transmit RF field used. Thus, in principle, a single RF receive coil could be used to generate multiple receive field sensitivities for different acquisition windows of a process that uses different transmit RF fields. Herein a coil denotes a wide variety of electromagnetic structures including at least one loop of a conductor, to more complicated components of complex coil arrays, and certainly includes birdcage coils, Helmholtz coils and the full variety of coils commonly used in the art. Given the prevalence of receive coil arrays in commercially available MR systems, and the diversity of sensitivities of these coils, it is expected that sequential and/or parallel receive field acquisitions will typically provide respective receive field sensitivities.

Once the receive field sensitivities have been mapped, the B0 field inhomogeneity is identified (step 12). This may be determined in two ways. The inhomogeneity may be determined empirically. Alternatively, it may be determined by iterative approximation. In step 14 the sensitivity maps and inhomogeneity are used to compute a process for combining MR signals associated with respective RF receive fields. In general, MR signals are a data stream of digitized amplified samples (a variety of preprocessing steps may be performed), each taken in a sequence from a respective channel (associated with a respective RF receive field). This is a time-domain representation of the MR signal, and may be a free induction decay signal, or an echo. A Fourier transform of the time domain representation may be performed to generate a frequency domain representation of the MR signal. The process for combining may involve application of various operators and transforms to the MR signals prior to a combining operation, however, for simplicity, Applicant currently prefers combination in the time domain, to synthesize a MR signal, for example, as a linear combination of corresponding samples of the MR signals associated with the respective RF receive fields. The linear combination varies as a function of sample time (preferably typically in terms of both phase and amplitude).

Optionally, in step 16 the process may be applied to a plurality of MR signals of respective RF receive fields. If so, the output of the process may be an MR image or a MR spectrum. An error parameter may be computed with respect to the output, and that may be used to guide the computation of another process for combining the MR signals. This method may iterate until a desired error parameter is reached, a combining process is determined to be optimal (or locally optimal), or until a satisfactory image or spectrum is otherwise obtained. Thus the correction provided may be in the form of an image or spectrum embodying the correction (a method concurrent with, or retrospective of, a MR process), or the process of combining the MR signals itself (a method for calibration or preparation for a MR process).

The process may further comprise a trade-off between a well-shimmed output, and a high signal to noise ratio (SNR) output. For example, weights applied to the MR signals may be calculated according to an error limiting procedure so as to limit undesirable effects such as excessive noise amplification. The error limiting procedure may involve computing an error function from the output, or may be guided by a heuristic. Various techniques are known in the art for iterative approximation of a solution to such a problem. One class of methods particularly well suited are regularized optimization.

### Theory

The following theory is provided to explain how the RF receive fields may be combined in a manner that reduces B0 field inhomogeneities. This theory is described using conventional notation and terms that are well known in the art.

### Precession

In any NMR or MRI experiment, following spin excitation the nuclear magnetization precesses at a resonant frequency, determined by the Larmor Equation 1: ω₀=−γ(1−σ)B0. This is a general equation. The resonant frequency ω₀ can vary spatially and/or temporally. The gyromagnetic ratio is a fixed property of the nucleus that is precessing, and σ (<10⁻⁵) is the chemical-shift shielding. In many MR experiments, there remain unwanted B0 terms which modify the phase of the spin magnetization, m. Unwanted B0 terms can cause the precession rate to vary both spatially and temporally resulting in erroneous phase accumulation, leading to phase shifts and phase dispersion (‘dephasing’). We can write the total B0 field as Equation 2: B0(r,t)=B0⁰+B0^{EXPT}(r,t)+B0^{ERR}(r,t), where B0⁰ represents the static, uniform field, B0^{EXPT}(r,t) is any desired B₀ field modification (such as an MRI readout gradient); and B0^{ERR}(r,t) represents error terms including uncorrected shim fields and eddy current fields. The spin magnetization phase (θₘ) is the time-integral of angular frequency, so by integrating EQ2, we get Equation 3 θₘ(r,t)=φ^{INIT}(r)−γ(1−σ) B0⁰(t)−γ(1−σ)∫₀^{t} B0^{EXPT}(r,t)dt−γ(1−σ)∫₀^{t} B0^{ERR}(r,t)dt. The first term φ^{INIT}(r) is the initial phase distribution following spin excitation, and will depend upon the both the transmit coil construction and the transmit pulse phase. We do not treat it as an error term. All error terms are understood to be included in B0^{ERR}(r,t).

The actual precessing magnetization (in the sample), m^{ACT}, experiences all the B0 terms of EQ3. The correct (desired) magnetization m^{CORR} is related to the actual magnetization by a phase factor depending upon B0^{ERR}(r,t) term, of the form of Equation 4: m^{CORR}=m^{ACT}(r,t) exp [iγ(1−σ)∫₀^{t} B0^{ERR}(r,t)dt]. In an experiment we want to observe the electromotive force (emf) from m^{CORR} but actually we observe the emf from M^{ACT}.

### MR Detection by EM Induction

To begin with a quote from Hoult & Lauterbur [1]: “ . . . if a conductor carrying unit current produces a field B₁ at point P, then a rotating magnetic dipole m placed at point P introduces an emf in that conductor given by: emf=−δ/δt[B1·m]=δ/δt[|B1∥m| cos θ]. For the NMR case, m may be considered to be the nuclear magnetic moment flipped in the usual way from the z direction into the xy plane by the application of a 90° pulse” (1,2). To calculate the emf produced by a volume of sample, Equation 5 (from the quotation) is integrated over the volume (Hoult and Richards, 1976). Note from its definition in EQ5, B1 is not an actual field present during detection. It is simply a very convenient means of calculating the emf. We will refer to the B1 in EQ5 as the ‘receive field’ or ‘detector field’.

EQ5 is general and accommodates both temporal and spatial variations of B1 and m. For practical MR receiver coils, the magnitude and phase of B1 will vary to some degree over the sample volume. However for almost every MR experimental situation, the B1 field pattern is static, with the RF time variation arising from the rotating magnetic dipoles and so contained within the phase of m, and thus also θ. It is worth emphasizing that B1 does not oscillate at an RF frequency—in an ordinary MR experiment there is in fact no time-dependence of the detector B1 field at all. For [B1·m] to exhibit time-dependence (and so generate an emf by EQ5) it is sufficient that only one of B1 or m vary.

### Correction of B0 Precession Errors

So precession errors in m^{ACT} would be counteracted, and m^{CORR} recovered, if we had a time-dependent detection field B1^{CORR} satisfying Equation 6: emf^{CORR}=−δ/δt[B1^{CORR}(r,t)·m^{ACT}(r,t)]=−δ/δt[B1^{STATIC}(r)·m^{CORR}(r,t)]. This condition introduces a new field B1^{CORR} which, when acting as detector for the actual magnetization, yields the same emf as given by some static field B1^{STATIC} detecting the correct magnetization. We of course know that a static detection field applied to the correct m yields a correct emf, because the only time variation in the dot product is due to evolution of the re-phased signal m^{CORR}. We have written the detection field B1^{CORR}(r,t) as time-dependent and will show below that this is necessary. We can simplify the condition (EQ6) by noting that it is sufficient that the dot products be equal: B1^{CORR}(r,t)·m^{ACT}(r,t)=B1^{STATIC}(r)·m^{CORR}(r,t). Substituting m^{CORR} from EQ4, performing the dot product on the right hand side, and re-arranging to associate the phase error term with the B1 field rather than m, it is noted that this constraint is satisfied by Equation 7: B1^{CORR}(r,t)=B1^{STATIC}(r)·e exp [−iγ(1−σ)∫₀^{t} B0^{ERR}(r,t)dt]. What has happened here is that the symmetry of the dot product operation has allowed the phase dependence to be transferred from the m vector to the B1 vector. In both B1^{CORR} and m^{ACT}, the term relating to B0^{ERR} appears in the exponent with the same sign, i.e. the B1 phase correction tracks the magnetization phase error, so that after the dot product is performed that term has disappeared.

The conclusion is that an MR signal can be rephased by a receive field that is the product of any static field and a spatial phase correction term. This correction, can take many forms, as required.

To review: we have outlined a method for rephasing ‘dephased magnetization’ without applying an appropriate B0 field gradient. It is the emfs that are being manipulated, not the spins themselves. In MR, the magnetization is observed indirectly, through emfs generated by electromagnetic induction. In this detection process the detector B1 field acts as an intermediary, so that spin phase and emf signal phase distributions are not necessarily identical.

### Synthesis of Detection Fields

This section introduces the principles by which a time-varying detection field can be obtained. EQ7 calls for a time-varying B1 receive field, however the construction of some sort of flexible RF coil is not required. Rather, a B1 detection field can be synthesized by the weighted combination of multiple receive signals acquired with different respective spatial sensitivities. One way to collect this data is to employ an array of receiver coils as used in typical multi-channel MR spectrometers. The detection field that is synthesized is determined by the individual receiver spatial sensitivities and the chosen weighting functions.

The detection equation, EQ5, can be applied to each coil separately. Consider two receiver coils P and Q, from EQ5: emf^{P}=−δ/δt[B1^{P}·m], just as emf^{Q}=−δ/δt[B1^{Q}·m]. Post-acquisition, each emf is represented digitally by a respective time series of samples. We choose to combine the two digitized emfs by weighted addition with weights w^{P}(n) and w^{Q}(n). We will combine the acquired coil signals with coil weights that in general may vary throughout the acquisition window. For the n^{th} pair of samples in each dataset (P(n) & Q(n)) we can calculate a composite according to Equation 8: emf^{TOT}(n)=w^{P}(n)emf^{P}(n)+w^{Q}(n) emf^{Q}(n). Substituting the definitions of emf^{P} and emf^{Q}, moving the weights (constants) within the brackets and rearranging, and then combining the two dot products yields Equation 9: emf^{TOT}(n)=−δ/δt {(w^{P}(n) B1^{P}+w^{Q}(n))B1^{Q})·m}.

The combination of the two emfs at this sampled time point (n) therefore yields a signal identical to one which would be obtained from a coil with the field pattern: B1^{TOT}(n)=w^{P}(n) B1^{P}+w^{Q}(n) B1^{Q}. This is how receive fields can be synthesized retrospectively (i.e. post-acquisition): by combination of signals from multiple receive fields. Because the form of the detection equation is unaltered we can still meaningfully talk about B1 fields and emfs, even though everything is occurring in the digital realm. We have a time-dependent B1 receive field, where the time-dependence is introduced by the weighting functions.

Naturally synthesis can be generalized to an arbitrary number of coils, generally with increasing advantage. The synthesized B1 field acts as a receive field, yielding a total emf signal equal to a signal that would have arisen if the component fields had been combined with the specified weights. This is how time-dependent B1 field patterns are created.

Now what is required is to find weights for the samples, for a given correction. The weights are then used to perform the reconstruction by the weighted summing of samples having a same sample number, having regard to the receive fields of the respective samples. It is easy to see that for a single set of measurements there exists a single theoretically ideal time-dependent B1 field that would correct any gradient in the B0 field, but it is equally evident that a random selection of weights for the samples would severely impair the MR output.

### Case 1 Correcting a Linear Static B0 Gradient

The first example of an inhomogeneity that can be corrected is the case of an imperfectly shimmed B0 field. An unshimmed linear, constant B₀-field gradient, i.e. appearing as B0^{ERR}=xGₓ. Substituting this into EQ4 yields m^{CORR}=m^{ACT}(r,t) exp [iγ(1−σ)xGₓt], as the integral is trivial with Gₓ being a constant. Substitution into EQ7 yields B₁^{CORR}(r,t)=B1^{STATIC}(r)·exp [−iγ(1−σ)xGₓt]. By construction the emf resulting from using B1^{CORR} as a detector field will cancel out the error term, so that ω_{EMF}=ω₀+ω_{EXPT}. The precession frequency of the spins (ω_{P}) is therefore: ω_{P}(r)=ω₀+ω_{EXPT}+ω_{ERR}. So if ω_{D}=ω_{EMF}−ω_{P}, ω_{D}=γ(1−σ)xGₓ.

This means that the correction for a static B0-gradient is a detection frequency gradient. B1^{CORR} can be regarded as containing a linear detection frequency gradient (G^{D}) where Gₓ^{D}=δω_{D}/δx=γ(1−σ)Gₓ (Equation 10). The units of Gₓ^{D} are rad/(sec·m). B1^{CORR} can be rewritten as B1^{CORR}(r,t)=B1^{STATIC}(r)·exp [−iGₓ^{D}xt] to show that the phase of the B1^{CORR} field evolves both in space (x) and in time (t).

It is worth noting the appearance of the gyromagnetic ratio in EQ10. The Gₓ^{D} that appears in EQ10 is the DEFG required to completely shim-out the B0-gradient (defined for this example to be Gₓ). Therefore a larger amplitude DEFG is required for higher γ nuclei—because dephasing occurs more rapidly. This is different from B0-shimming where the same static (or low frequency) B0 shim electromagnets that correct emfs from all nuclei. This fact in itself does not represent a problem because the DEFG is defined retrospectively. The effect of the chemical shift shielding constant σ is typically negligible.

### Case 2 Correcting a Gradient Waveform

Case 1 above was a special case, albeit a common one. One generalization is to allow the gradient error field to vary over time. Practical instances of time-varying gradient error fields may be encountered due to B0-gradient induced eddy currents. For example, if we have B0^{ERR}=xGₓ(t), the resulting detection frequency gradient Gₓ^{D}(t)=δω_{D}/δx=γ(1−σ)Gₓ(t). This implies that the detection frequency gradient is no longer static, but is in effect, a pulse-sequence gradient waveform that is defined post-acquisition. So Gₓ^{D}(t) is a waveform defining the strength of the x-direction detection frequency gradient. This technique therefore has potential application in counteracting dephasing caused by fields from eddy-currents present throughout the acquisition window. A varying detection frequency gradient may also be useful if the desired strength cannot be implemented throughout the acquisition window. Further examples of types of inhomogeneities can equally be applied by substitution into the given formulae.

### Reconstruction

So, given a desired B1^{CORR} field, and the associated detection frequency gradient G^{D}, the question remaining, is how do we select weights for a particular receiver array. The solution involves knowledge of the coil field maps within the target volume (i.e. the voxel to be shimmed).

Consider the case of reconstruction of a spectrum from a set of FIDs. The method is also valid for echo data—the main difference being that for echoes the in-phase condition is at the center of the acquisition window, whereas for FIDs it is at the beginning. The overall process involves generating a corrected FID sample-by-sample, and then performing a fast Fourier transform (FFT) in the usual way. Each sample in the emf is reconstructed independently, with (in general) a different target field. Three types of data are needed for the reconstruction: 1) a set of NC (number of coils) sample data streams of complex emf values in each sample acquired from a receive array with all data originating from the same target volume (e.g. voxel); 2) B1 sensitivity maps over the target volume, for each of the NC receive fields; and 3) the target detection frequency gradient (G^{D}). Each coil sensitivity map is defined over the target volume as NP (number of field points).

The presently preferred reconstruction algorithm permits any spatial arrangement of field points to be used, because the points are rearranged into a 1D list for matrix operations. Some results indicate that a spherical volume (with points in a regular 3D grid) tends to produce better results than a cuboid. (In some cases a field fit to a cuboid volume may fit at the corners at the expense of the center of the volume, which is undesirable).

It is assumed there is a receive coil array with NC coil elements, each attached to its own receiver channel. For each receiver channel, a map of the complex field sensitivity (magnitude and phase) at each field point is required. The coil maps are not the raw detector coil field patterns, but rather the sequence sensitivity for the voxel. So for a localized MRS sequence (e.g. PRESS), the coil maps should only be non-zero within the PRESS voxel. The coil sensitivity matrix A_{PC} (dimensions np×nc) tabulates the B1 sensitivities of each coil at each point.

The present procedure assumes that there is no noise correlation between receiver channels. If in reality if this is not the case, then a pre-whitening step can be applied to the original data to produce virtual receiver channels with uncorrelated noise, or regularization may be used to avoid excessive amplification of any correlated noise in the receiver channels.

It is necessary to determine, in some manner, the precession error function for the target volume. This might be available as a priori information from a B0-field mapping or from eddy current measurement. Otherwise it needs to be determined or estimated by other means.

In analogy with how conventional shimming is sometimes performed, the precession error may be estimated from the emf dataset itself. This would be a retrospective analog of a conventional shimming method (e.g. iterative adjustment). The retrospective nature of this method means that, although it will be useful to know the actual precession error, it may not always be necessary, as data is in no way spoilt by any attempts. Indeed a computationally expensive search for an optimum solution by rote is one possible mechanism for determining the precession error.

In general, for reconstruction of an FID of length NR, the number of different target functions NT required equals NR, i.e. a different target for each sample in the acquisition window, although in some circumstances NT<NR may be sufficient. The form of the target field B1^{CORR}(r,t) may be as given as the product of a static field and a phase factor. In some embodiments, the correction functions would be chosen to fully cancel the target throughout the whole acquisition window and over the entire target volume, and the static B1 field would be uniform. However often this may not be possible and/or practical, due to the limited B1 fields available over the target volume, and the necessity of limiting the noise amplification in the reconstruction. In such cases the reconstruction (by choice of target field and regularization strategy) may be designed to optimize specific parameters such as: spectral SNR, spectral resolution, or uniformity of sensitivity over the target volume.

There are a number of parameters that may influence the selection of specific reconstructions in specific MR processes. For example, NC, the number of receiver coils in total, and the number that are available within the target volume, the voxel volume relative to the coil size, the voxel location, and the type and severity of the precession error. These parameters affect what precession errors are correctable, and to what degree. A generally more favourable situation is: a larger voxel; a larger number of receiver coils with good sensitivity over the voxel; and a variety of receiver B1 field patterns within the voxel. For imaging corrections (e.g. EPI) the voxel may correspond to part or the whole imaging FOV (field-of-view). The static B1 field may be chosen with uniform phase and may or may not have uniform magnitude over the voxel. The correction term may be chosen to fully or partially correct for the precession error. There are at least three possible departures from the ideal: the target function may not be specified to completely annul the precession errors (either by deliberate choice or though ignorance of the true precession errors); the solution found may not match the target function; there may be noise amplification (SNR loss).

The noise-level of the technique depends upon the receive coils used to synthesize the polynomial field terms. There is not a direct relationship between field component and noise, i.e. the same B1 field component could be produced by quite different coils e.g. small coils close together, or large coils further away. The noise level depends upon the coil size. So the coils used to implement the field components will strongly influence the noise level.

Fundamentally, it is not the strength of the detection frequency gradient itself, but rather the maximum degree of phase dispersion in the detector field that can be generated over the voxel, that is the limiting factor in defining the B1 target detection field (phase dispersion=maximum phase−minimum phase). There are limitations on the phase dispersion that can be achieved without unacceptable noise amplification, and this may depend upon orientation. For the case of a linear detection frequency gradient, three such limits can be defined (one for each axis). Analysis of the Taylor expansion of sine and cosine field functions as polynomials provides insight into the maximum available phase dispersion.

Assuming the simplest case, the complex weights W_{c} for each of NC coils for a given sample number, given the complex coil field maps A_{pc} and target complex field Bₚ, can be solved with the following complex matrix equation: Bₚ=A_{pc} W_{c}, where p indexes the field point, and c indexes the coils. The sensitivity matrix may be inverted using a Tikhonov regularized least squares method (8). Regularization is used to control noise amplification. The Tikhonov matrix is set to favour the use of the detector coils with higher sensitivity over the voxel, and so to limit noise amplification.

Concluding the theory section, it is noted that the key purpose for rephasing the MR signal is to increase the amplitude of the resultant vector to allow better measurement. However, signal loss from dephasing is not a simple linear function of the maximum phase dispersion angle. While small amounts of dephasing can cause negligible signal loss, larger amounts can annul the signal.

The potential gain in signal amplitude by a signal rephasing operation therefore depends upon two main factors: the initial level of dephasing; and the amount of rephasing applied. Considering just a single sample only, the SNR increase on rephasing may vary from negligible up to an infinite factor! This latter case occurs when a completely dephased signal is rephased sufficiently to appear above the noise level. So in the time-domain the SNR gain from the shimming procedure depends sensitively on the behaviour of the MR signal (dephasing and rephasing levels). So from a time-domain point of view, since the benefits vary widely, so does the acceptable cost (in terms of noise amplification). That is—the optimum regularization depends upon signal phase dispersion and the achievable correction field. There is therefore an interplay between sample, regularization, and target function.

Although rephasing is performed in the time-domain, for MR spectroscopy, it is the ability to distinguish and measure signals in the frequency domain that is primary. Some of the related issues are: lineshape, linewidth, line overlap and spectral resolution. A fundamental limitation for MR spectroscopy is line-broadening due to an inhomogeneous B0 field. B0 shimming is therefore an essential and routine part of an MR spectroscopy procedure. The ultimate purpose of shimming is to optimize the ability to measure peaks. The spectral lineshape is the Fourier transform (FT) of the time-domain signal decay envelope. The DEFG shimming method can play a role in the manipulation the lineshape by rephasing the beginning of the FID.

### Example 1

### MR Spectroscopy

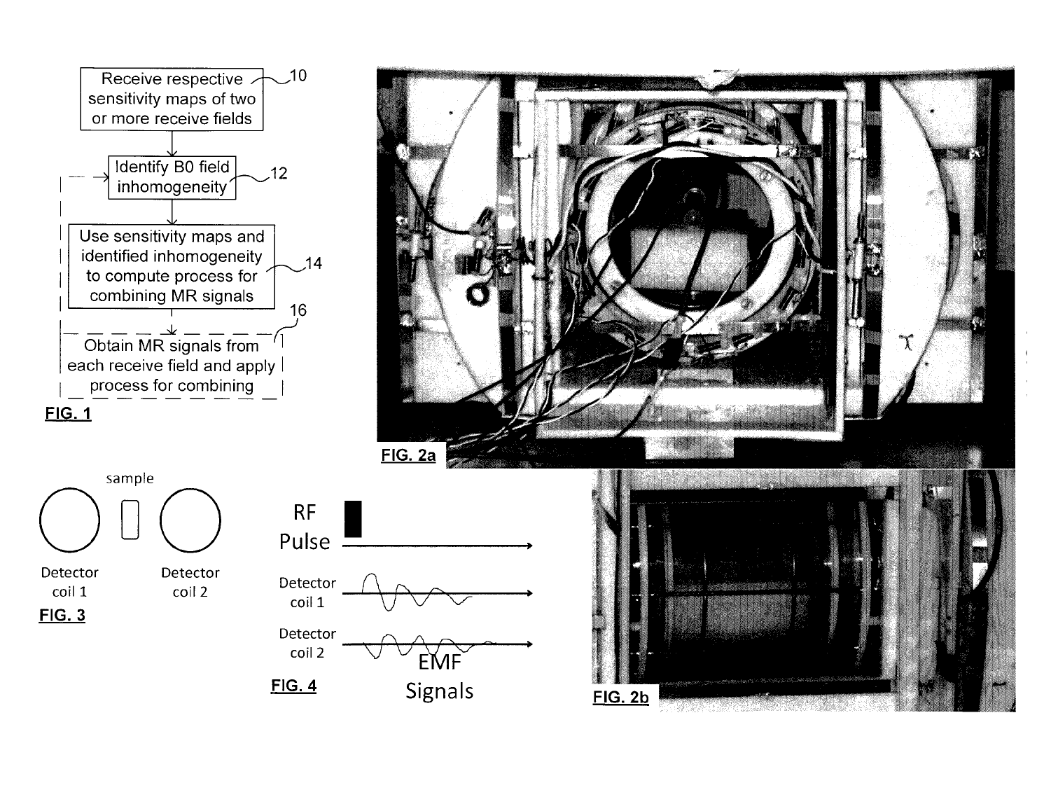

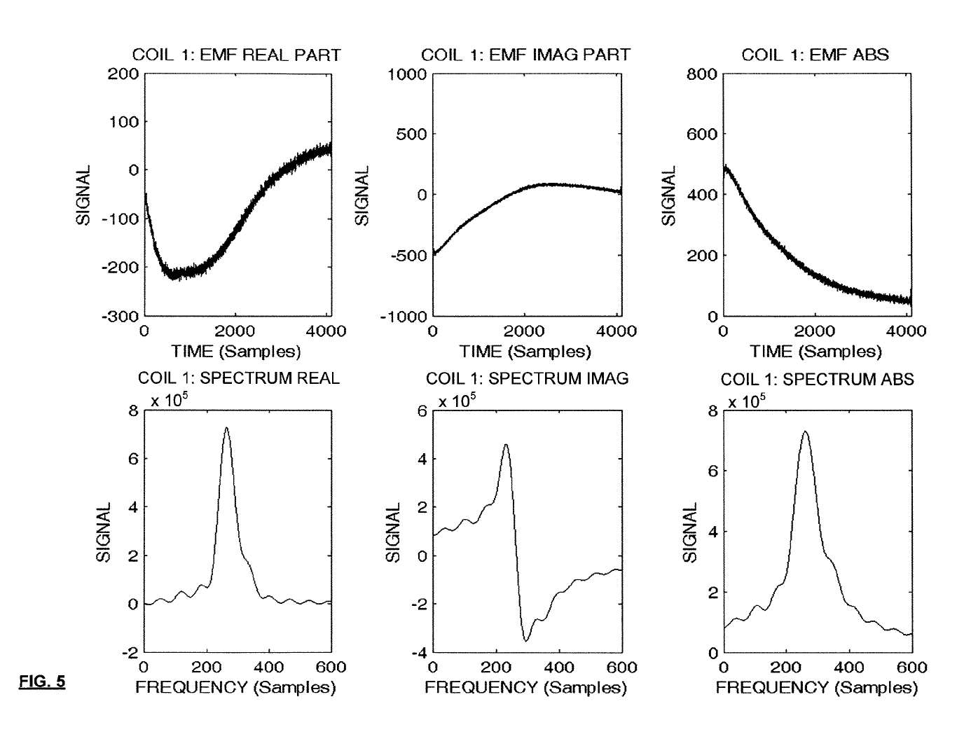

Experiments were performed on a 0.2 Tesla MRI system (i.e. B0=0.2 T). For this field strength, the resonant RF frequency is around 8.2 MHz. The sample used was a tube of deionized water. Tube size was 100 mm×14 mm (diameter). FIGS. 2a,b shows photographs of the coil array and the sample (front and longitudinal views, respectively). FIG. 3 shows a highly schematic view of the coil array and sample.

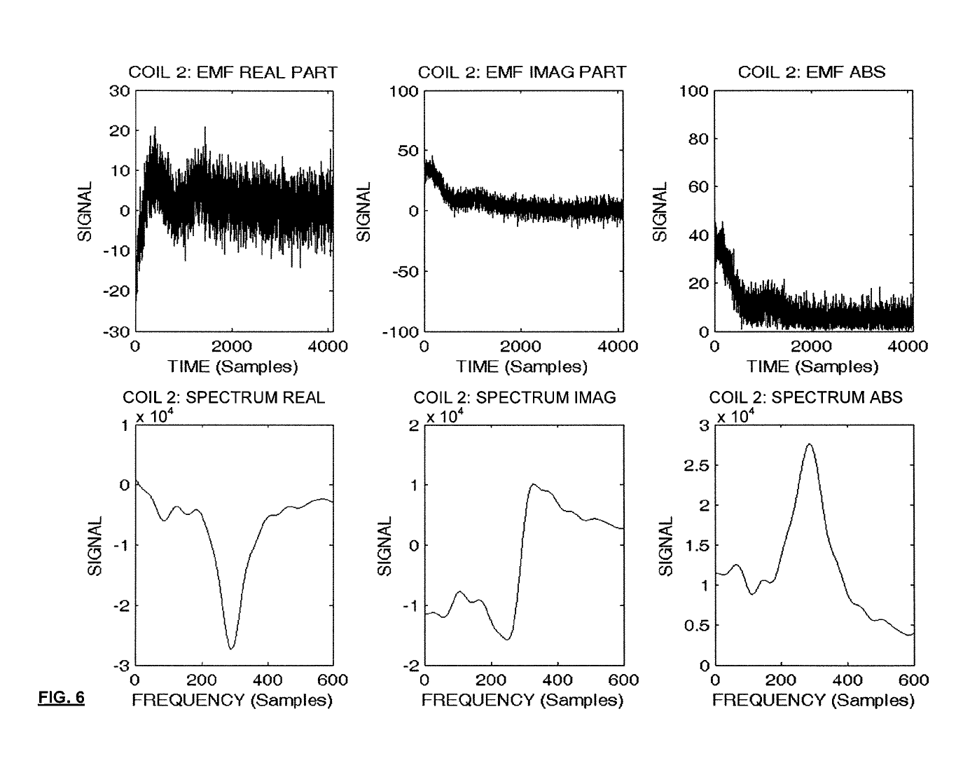

An NMR experiment was performed with two receiver coils. Each receiver coil signal has its own receiver channel. The experiment starts with the transmission of an RF pulse. For this experiment, coil 1 was used at the transmitter. Following the excitation, emfs are received on both receiver coils. FIG. 4 shows the NMR measurement as a pulse sequence diagram. It shows the transmitted RF pulse and the collection of 2 emfs (FIDs) following this pulse. This is a very basic MR procedure in which an RF pulse is generated, and an acquisition window follows. Parallel acquisition by the two coils is shown with schematic emfs.

In this experiment Coil 1 (a Helmholtz coil) was designed to have an approximately uniform receive sensitivity. Coil 2 was designed to have a linear sensitivity with a null in the central plane. These sensitivities were confirmed by MRI experiments.

The sample was shimmed using the linear B0 shim coils. The Gz shim was then set to 0.5 μT/m off from the optimum value to cause a line-broadening (shorter emf). The direction of this linear gradient offset is along the axis of the water tube. Data was collected in this condition.

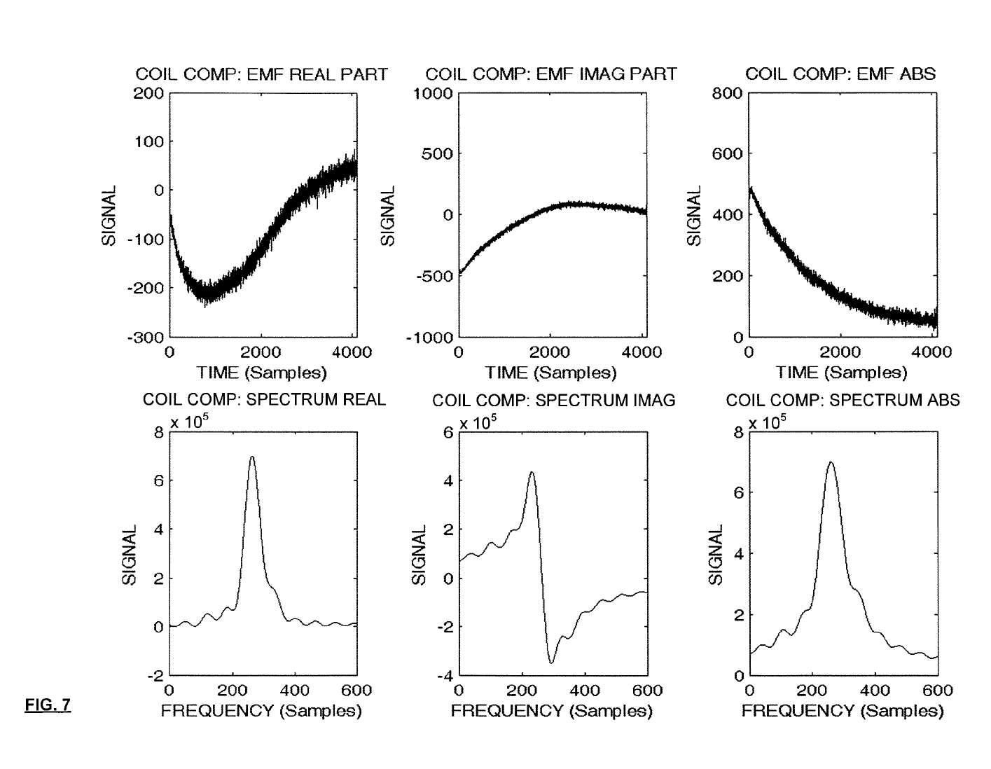

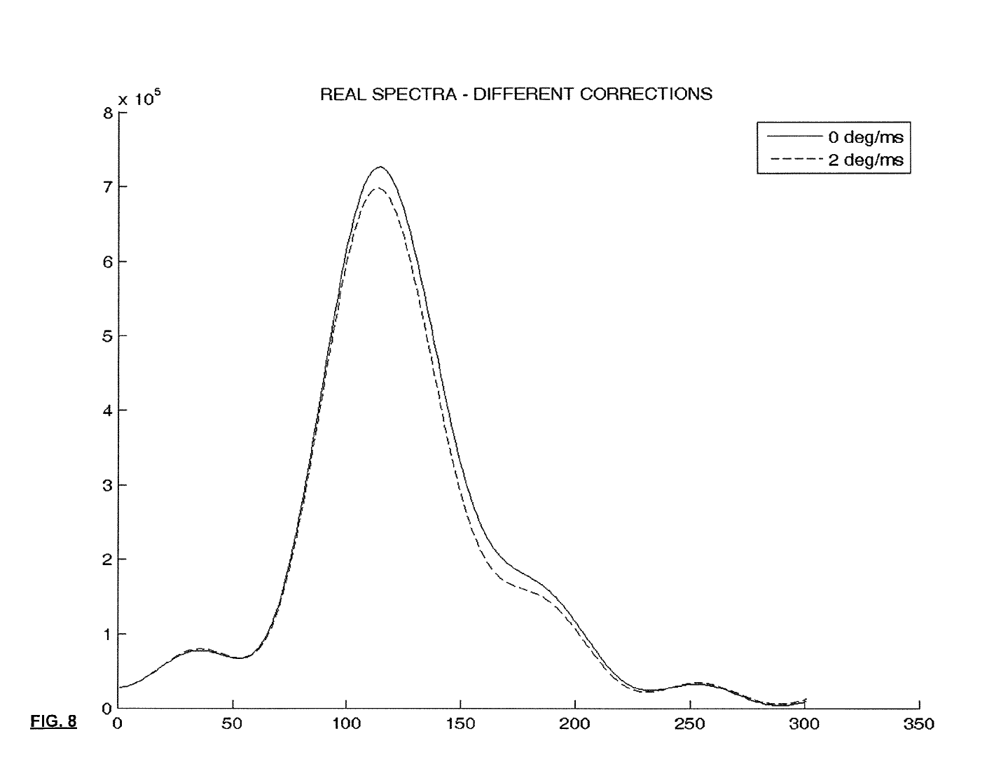

FIGS. 5 and 6 are graphs showing emf and spectra (i.e. the receive FID data in the time domain and frequency domain respectively) for each coils. Specifically the real, imaginary and absolute values (magnitude) were plotted. FIGS. 5 and 6 (and FIG. 7 as well) each contain 6 plots. FIG. 5 shows data from coil 1. FIG. 6 shows data from coil 2. The top three are time-domain signals (emfs) are FIDs. The bottom three are frequency-domain spectra of the FIDs. The spectra are obtained by Fourier transformation (FT) of the time-domain data. The spectral plots show just the central part of the spectrum, to show the detail of the spectral line of water.

A weighted combination of the acquired emfs (FIDs) is used to generate a corrected emf. To generate the combination, the gradient field offset was used as the target error field to be corrected. The known coil sensitivities over the volume to be shimmed were used to calculate the time-dependent weighting.

Coil 1 is a uniform coil, i.e. a field with zero phase gradient. The combination of coil1+coil2 represents a phase gradient. To approximate a phase gradient of increasing strength the weighting function used was 1.0 for coil 1 and for coil 2 a weighting increasing linearly with time from 0 to a maximum of 2. After the weighting for coil 2 reached a maximum it was kept constant until the end of the emf. The use of these coils and this weighting procedure provides an approximation to an ideal combination. FIG. 7 (top) shows corresponding plots for the composite emf synthesized signal. This was Fourier-transformed to produce the corresponding spectra FIG. 7 (bottom).

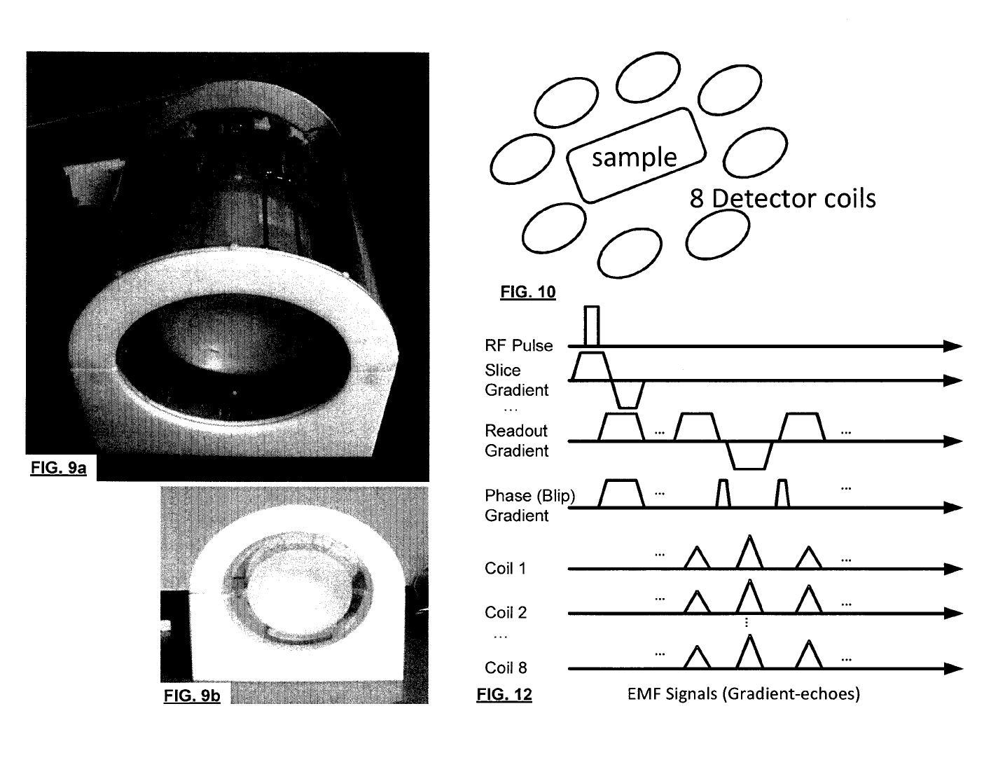

FIG. 8 shows uncorrected (i.e. coil 1 data: labeled 0°/ms) and 2°/ms spectra overlaid. An improvement in linewidth provided by a 2°/ms correction over the uncorrected spectrum. The line-width was measured using full-width-at-half-maximum (FWHM). The results for the real spectra as shown were FWHM=62 for uncorrected data, i.e. coil 1), and FWHM=60 for the corrected data. The corresponding values for the absolute plots (not shown) were 101 and 96. A lower FWHM is good, as the aim of the adjustment is to eliminate line-broadening due to B0 field inhomogeneities. This corroborates simulation results.

### Example 2

### MRI (EPI)

Experiments were performed on a 3 Tesla MRI system (i.e. B0=3 T). For this field strength, the resonant RF frequency is around 128 MHz. The sample used was a 12 cm diameter container. The container was filled with standard surgical saline (9 g/L NaCl) made from nanopure distilled water.

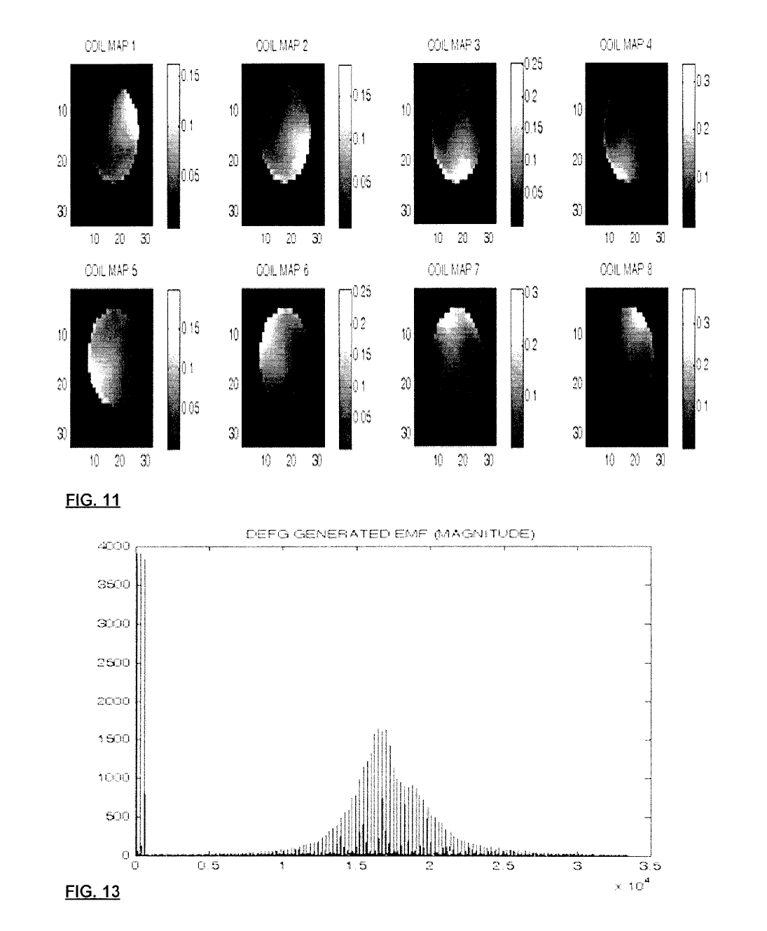

An MRI experiment was performed with eight receiver coils. FIGS. 9a,b show photographs of the coil array and the sample. FIG. 10 shows a schematic view of the coil array and sample. Each receiver coil supplies an emf signal to its own receiver channel. The experiment starts with the transmission of an RF pulse. For this experiment, a separate body coil was used at the transmitter. Following the excitation, emfs are received on all receiver coils.

The receiver coil spatial responses were determined by an MRI mapping experiment in which the image intensity is proportional to the coil sensitivity. FIG. 11 shows the receiver coil maps.

Conventional B0 gradients are used to perform spatial encoding. A gradient-echo EPI (echo planar imaging) MRI sequence was used. In this EPI experiment all data to reconstruct a two-dimensional image is collected as a series of gradient echoes after a single slice-selective excitation pulse. FIG. 12 shows the NMR measurement pulse sequence diagram. It shows the transmitted RF pulse and the collection of emfs during acquisition windows, at respective receive channels (respective coils). It also shows the gradient encoding.

The sample was shimmed using the linear B0 shim coils. An image was collected. FIG. 13 shows a time series of echoes as a combined signal from the 8 receive channels. The 3 echoes at the left are reference echoes used to perform a phase correction during reconstruction.

The Gy shim was set to 1 μT/m off from the optimum value to cause a line-broadening (shorter emf). Data was also collected in this condition. Thus data was collected in both the shimmed condition and in the mis-set shim condition.

A volume to be shimmed within the phantom was chosen. A target shim correction was selected, based on the known shim error, which had been deliberately introduced. The emf weighting functions were calculated based on the coil sensitivity maps over the volume to be shimmed and the target correction. A time-dependent weighted combination of the acquired emfs was used to generate the corrected emf using the detection frequency gradient method. Standard EPI reconstruction code was then used to reconstruct an EPI image from the single corrected emf. This involves phase corrections, data reordering and Fourier transformation. Two comparisons were made.

The first comparison (shown in FIGS. 14a,b) demonstrates the effect of a mis-set shim on the EPI method. This comparison is for reference and does not use our detection frequency correction at all. Images were reconstructed using the conventional sum-of-squares reconstruction for both the well-shimmed case and the mis-set shim case. The images are slightly different, but this is barely visible.

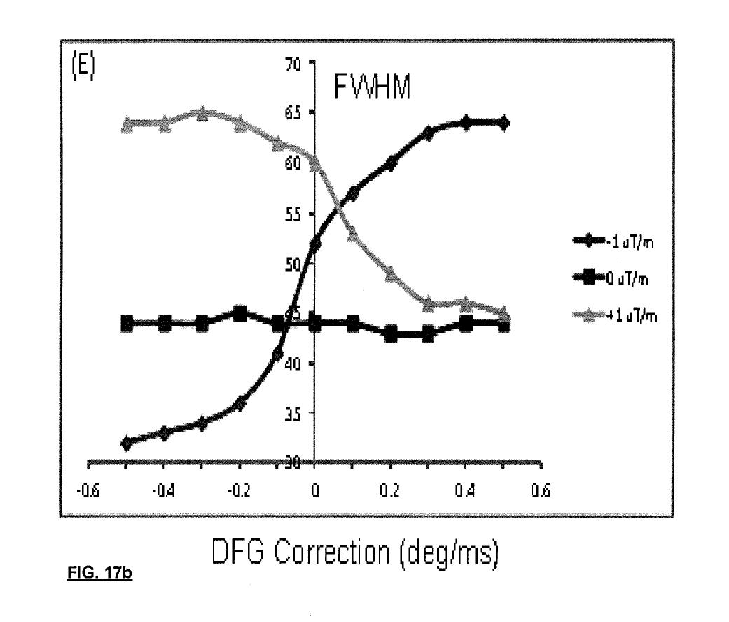

In EPI the effect of the mis-setting of a linear shim, (as we used here) is to stretch or shrink the image along a single axis (the phase or ‘blip’ direction, which is vertical in the figures). By subtracting the two images (as shown in FIG. 16a) it can be seen that the main differences are thin rims at the top and bottom of the difference image.

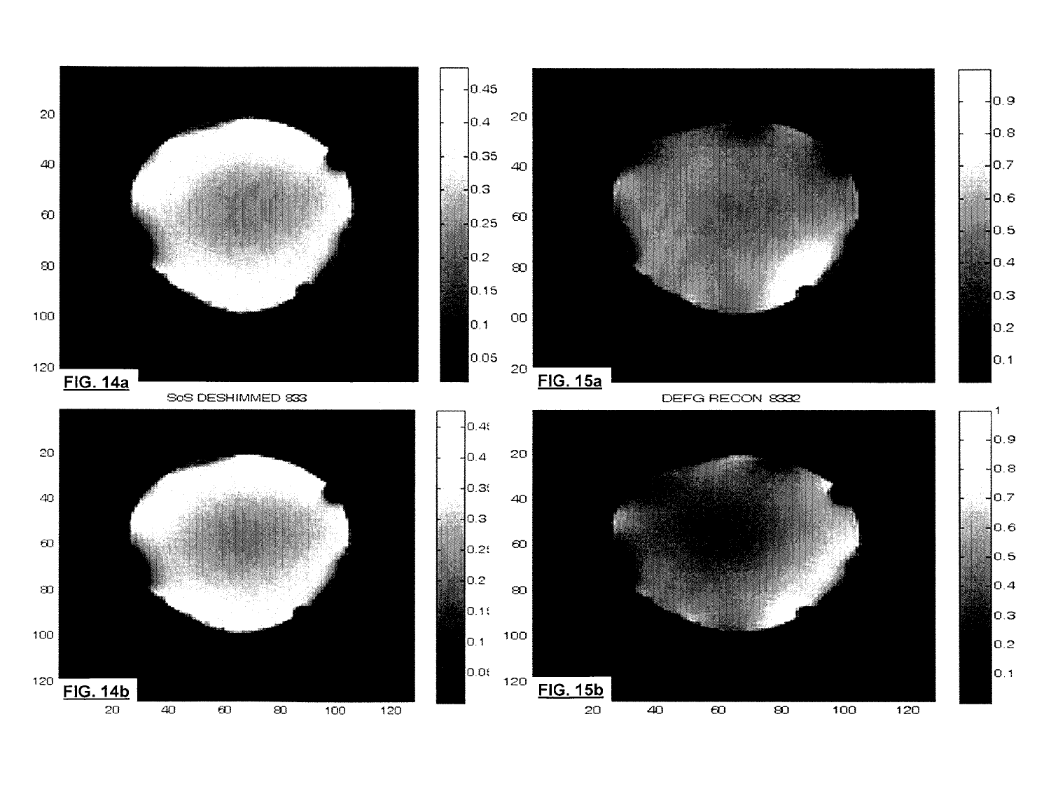

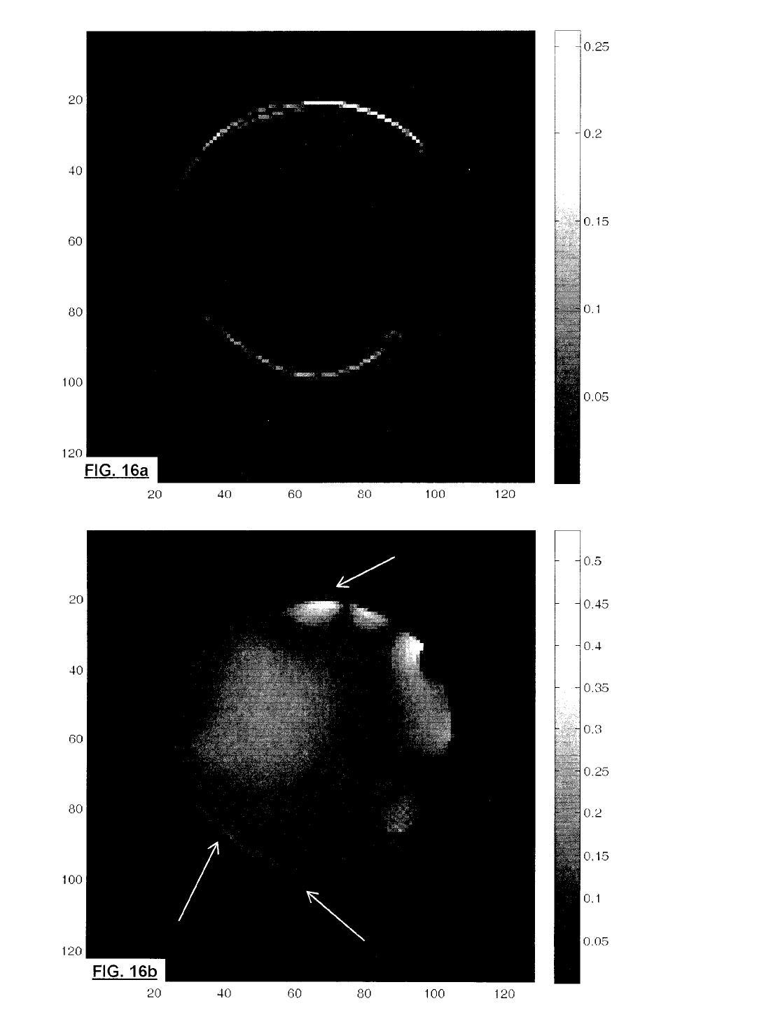

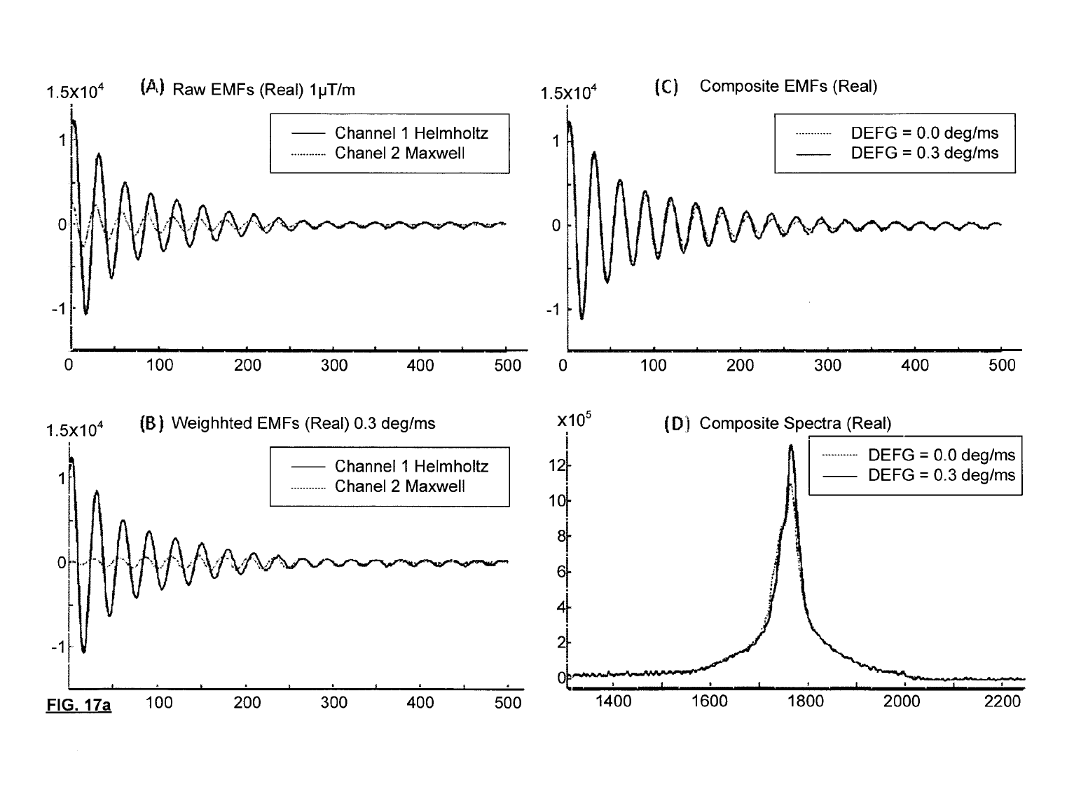

Second comparison: The correction algorithm was run twice, first will a null target field, then with the correct target correction. The resulting two magnitude images are shown as FIGS. 15a,b, and subtracted to show a magnitude of the difference as shown in FIG. 16b. This is a sensitive test for how the choice of target field correction affects the final image. The rims of the phantom showing high difference (high intensity) are annotated with arrows.

Since the difference images FIGS. 16a,b show similar features, this is evidence that the DEFG reconstruction has a similar effect as a change in shim setting, and can be used to correct for shim errors. In a second version of this test, designed for more sensitivity, the images resulting from a positive target field correction were compared with those from a negative correction. The results of the second version show changes at the top and bottom image edges, similarly to that seen in the difference of the sum-of-squares reconstructed images. This is evidence that the correction is working successfully to compensate for the mis-set shim as it is causing an image dimension change (shrink or squash) as expected. Although the correction may not be complete, and there may be side-effects, this is sufficient to demonstrate the principle.

Further experimental data has confirmed the ability of the method to effect shimming. This experiment was performed using a 2-channel receiver system, at 0.2 Tesla on a custom MRI system (MRI Tech, Canada). The two coils corresponded to the uniform and linear terms in a Taylor series expansion of sine and cosine functions. Coil design and construction has been described elsewhere (Deng Q, King S B, Volotovskyy V, Tomanek B, Sharp J C. B1 Transmit Phase Gradient Coil for Single-Axis TRASE RF Encoding. Magnetic Resonance Imaging 2013 (In Press). A phantom containing distilled water, and of length 16 cm in the x-direction, was used to acquire FIDs for three different B₀ Gₓ shim settings (−1 μT/m, 0 μT/m, +1 μT/m). Reconstructions were performed for a range of detection frequency gradients in the x-direction.

FIGS. 17a,b are a panel of graphs showing the further experimental results. Graph A) shows raw, unprocessed FIDs from the two-channel array, with a deliberately applied shim offset of 1 μT/m. The Helmholtz and Maxwell coils correspond to uniform and x amplitude gradient fields, respectively. Graph B) shows the FIDs with time-domain weighting functions applied (i.e. shown before summation) to generate a DEFG of 0.3 deg/ms. Notice in particular that the Channel 2 signal weighting is zero at t=0. Graph C) plots two different reconstructions. The first (dotted), corresponding to zero DEFG, i.e. just the Channel 1 signal (uniform); the second (solid) is the summation of the 2 weighted signals shown in B). The latter shows slower signal decay, as expected for successful shimming. Graph D) is the Fourier transform of the signals in part (C). The DEFG=0.3 ms/deg signal (solid) has a better lineshape and higher peak, consistent with better shimming. Finally Graph E) (in FIG. 17b) plots spectral line width, evaluated using ‘Full-Width at Half Maximum’ (FWHM), as a function of strength of DEFG correction. Results are shown for 3 different initial B₀ shim settings (−1 μT/m, 0 μT/m, +1 μT/m). The 0 μT/m case corresponds to the well-shimmed condition. As expected, the sign of the DEFG correction resulting in narrower spectral linewidth (lower FWHM) depends on the sign of the initial shim error. The flattening of the graphs for higher DEFG values (over 0.2 deg/ms) indicates a diminishing effectiveness of the DEFG correction. The FWHM for the well-shimmed examples exhibit minimal effect of the DEFG correction.

FIG. 17a show an example dataset with successful shimming results in the time-domain C) and spectral domain D). The shimmed FID shows a slower decay and the shimmed spectrum shows a narrower, higher peak with a better shape. These results closely resemble the result of conventional shimming, confirming the theory.

In FIG. 17b, the effect on the spectral linewidth (FWHM) of a range of strengths and polarities of DEFG gradient are shown for the three experimental conditions. For the two conditions using shim offsets, one polarity of DEFG is shown to narrow the line, while the other broadens the line. This is precisely the same behaviour seen in conventional shimming and is strong confirmation that retrospective shimming is occurring as predicted. In both cases, the effectiveness of the correction has a limit and it is seen that beyond around 0.2 deg/ms the effectiveness of the attempted correction diminishes. This is expected as a result of the approximation employing only two terms in the Taylor series, effectively limiting the amplitude of the DEFG achievable.

The experimental data E) demonstrates that even a minimal implementation of just two receiver channels can be sufficient for significant shim improvement.

### REFERENCES

The contents of the entirety of each of which are incorporated by this reference.
[1] Hoult D I, Lauterbur P C. Sensitivity of the Zeugmatographic Experiment Involving Human Samples. Journal of Magnetic Resonance 1979; 34(2):425-433.
[2] Hoult D I, Richards R E. Signal-to-Noise Ratio of Nuclear Magnetic-Resonance Experiment. Journal of Magnetic Resonance 1976; 24(1):71-85.
[3] Sodickson D K, Manning W J. Simultaneous acquisition of spatial harmonics (SMASH): fast imaging with radiofrequency coil arrays. Magn Reson Med 1997; 38(4):591-603.
[4] Jakob P M, Griswold M A, Edelman R R, Sodickson D K. AUTO-SMASH: a self-calibrating technique for SMASH imaging. SiMultaneous Acquisition of Spatial Harmonics. MAGMA 1998; 7(1):42-54.
[5] Heidemann R M, Griswold M A, Haase A, Jakob P M. VD-AUTO-SMASH imaging. Magn Reson Med 2001; 45(6):1066-1074.
[6] Griswold M A, Jakob P M, Chen Q, Goldfarb J W, Manning W J, Edelman R R, Sodickson D K. Resolution enhancement in single-shot imaging using simultaneous acquisition of spatial harmonics (SMASH). Magn Reson Med 1999; 41(6):1236-1245.
[7] Skoch A, Jiru F, Bunke J. Spectroscopic imaging: basic principles. Eur J Radiol 2008; 67(2):230-239.
[8] Lin F H, Kwong K K, Belliveau J W, Wald L L. Parallel imaging reconstruction using automatic regularization. Magnet Reson Med 2004; 51(3):559-567.
[9] Ordidge R J, Cresshull I D. The Correction of Transient B0 Field Shifts Following the Application of Pulsed Gradients by Phase Correction in the Time Domain. Journal of Magnetic Resonance 1986; 69(1):151-155.
[10] Otazo R, Lin F H, Wiggins G, Jordan R, Sodickson D, Posse S. Superresolution parallel magnetic resonance imaging: application to functional and spectroscopic imaging. Neuroimage 2009; 47(1):220-230.
[11] Sharp J C, King S B. MRI using radiofrequency magnetic field phase gradients. Magn Reson Med 2010; 63(1):151-161.

Other advantages that are inherent to the structure are obvious to one skilled in the art. The embodiments are described herein illustratively and are not meant to limit the scope of the invention as claimed. Variations of the foregoing embodiments will be evident to a person of ordinary skill and are intended by the inventor to be encompassed by the following claims.

What is claimed is:

1. A method for correcting for B0 non-uniformity in a static magnet of a magnetic resonance (MR) apparatus, the method comprising:
obtaining a respective, different, field sensitivity map as a function of a sample volume for each of a plurality of RF receive fields of receiver equipment of the MR apparatus;
identifying a non-uniformity of the B0 magnetic field to be corrected; and
computing with the field sensitivity maps and the identified non-uniformity, a combination of the RF receive fields as a function of time that reduces artifacts in an MR signal acquired by the receiver equipment due to the identified non-uniformity.

2. The method of claim 1, wherein obtaining field sensitivity maps comprises mapping a field sensitivity for: each RF coil of an array of RF coils included in the receive equipment; each of a plurality of separate RF coils included in the receive equipment; and a RF coil in each of a plurality of positions, orientations and configurations in which the RF coil is adapted to be held during respective sample intervals of a MR procedure.

3. The method of claim 1 wherein obtaining field sensitivity maps comprises characterizing reception sensitivities of respective receiver coils.

4. The method of claim 1 wherein obtaining field sensitivity maps comprises characterizing reception sensitivities of a receiver coil for each of a plurality of transmit coil spatial variations.

5. The method of claim 1 wherein computing the combination of the RF receive fields comprises defining a weighted sum of the acquired MR signals is used to synthesize a new MR signal.

6. The method of claim 5 wherein the weighted summation is performed in the time domain.

7. The method of claim 6 wherein each of the MR signals consists of a data stream of digitized samples constituting a free induction decay (FID) signal or an echo.

8. The method of claim 7 wherein weights applied to respective samples to generate the synthesized MR signal are different for different samples of a same acquisition window.

9. The method of claim 8 wherein each digitized sample is a complex value, wherein the weights are defined by a weighting function that varies across the acquisition window both in amplitude and phase.

10. The method of claim 1 wherein computing the combination of the RF receive fields comprises computing a detection frequency gradient to correct for a linear B0 field gradient error.

11. The method of claim 1 wherein computing the combination of the RF receive fields comprises computing a sample weighting function to correct for a non-linear B0 field gradient error.

12. The method of claim 1 wherein computing the combination of the RF receive fields comprises computing a sample weighting function to correct for a time-varying B0 error field.

13. The method of claim 1 wherein computing the combination of the RF receive fields comprises computing a sample weighting function selected by applying an error limiting procedure to limit noise amplification.

14. The method of claim 1 further comprising providing MR signals associated with each receive field, and applying the combination to the MR signals to obtain a B0 corrected MR signal.

15. The method of claim 14 wherein application of the combination to the MR signals is used to compute an error function used in the error limiting procedure.

16. The method of claim 15 wherein the error limiting procedure comprises regularized optimization.

17. The method of claim 14 wherein the MR signals are free induction decay signals of a MR spectroscopy apparatus, in which the combination is selected to modify one of a line-shape and a linewidth.

18. The method of claim 14 wherein computing the combination and applying the combination are iteratively performed to improve an approximation of the non-uniformity.

19. The method of claim 14 wherein providing further comprises:
placing a sample in the sample volume of the MR apparatus; and
performing a MR process that includes acquiring the RF signals from the receiver equipment associated with each of the RF receive fields.
